(19) United States
(12) Patent Application Publication
(10) Pub. No.: US 2026/0351923 A1
(43) Pub. Date: Nov. 5, 2026

(54) OPTICAL MODULE

(71) Applicant: Seiji NAKANO

(72) Inventor: Seiji NAKANO

(21) Appl. No.: 19/124,498

(22) PCT Filed: Dec. 23, 2022
(86) PCT No.: PCT/JP2022/047584

§ 371 Date: Apr. 25, 2025

(51) Int. Cl. H01S 5/02315; G02B 6/12; H01S 5/02212; H01S 5/50

(52) U.S. Cl. CPC H01S 5/02315; G02B 6/12; H01S 5/02212; H01S 5/50; G02B 2006/12121; G02B 2006/12135; G02B 2006/12142

(57) ABSTRACT

An optical module of the present disclosure includes: a stem; a base part provided on a top surface side of the stem, and having a bottom surface portion opposed to the top surface of the stem, and a side surface portion perpendicular to the top surface of the stem; a sub mount provided on the side surface portion of the base part; a semiconductor integrated photonic device provided on the sub mount and composed of, from the top surface side of the stem, a semiconductor laser unit, an optical modulator unit, and an optical amplifier unit which are electrically independent; a semiconductor-laser-unit capacitor connected to the semiconductor laser unit; an optical-modulator-unit capacitor connected to the optical modulator unit; and an optical-amplifier-unit capacitor connected to the optical amplifier unit.

### TECHNICAL FIELD

The present disclosure relates to an optical module.

### BACKGROUND ART

In recent years, as various information terminals have been spreading and information is treated in a cloud, a data communication volume has been increasing. In order to meet a demand for the increasing data communication volume, a transmission rate in a base station of optical fiber communication is being increased and the capacity thereof is being increased.

As a light source for long-distance optical communication as in optical fiber communication, a semiconductor integrated photonic device in which a semiconductor laser unit, an optical modulator unit, and an optical amplifier unit are monolithically integrated is used (Patent Document 1). The optical modulator unit is a kind of external modulator. In the optical modulator unit, deterioration of a signal waveform is less as compared to a direct modulation method of directly modulating a laser beam intensity, and therefore optical fiber transmission at high speed and over a long distance can be performed. In addition, the optical amplifier unit functions to amplify a modulated light beam.

### CITATION LIST

### Patent Document

Patent Document 1: Japanese Laid-Open Patent Publication No. 2022-099537

### SUMMARY OF THE INVENTION

### Problem to be Solved by the Invention

In the optical module described in Patent Document 1, a semiconductor-laser-unit capacitor and an optical-amplifier-unit capacitor are provided in a shared manner as only one capacitor. In addition, the semiconductor integrated photonic device is provided in an oblique direction relative to a direction perpendicular to the surface of a stem.

In the optical module described in Patent Document 1, since the semiconductor laser unit and the optical amplifier unit are connected electrically in parallel, the same current flows through the semiconductor laser unit and the optical amplifier unit, and therefore it is practically difficult to control each unit independently.

The present disclosure has been made to solve the above problem, and an object of the present disclosure is to provide an optical module that is high in current controllability and enables size reduction.

### Means to Solve the Problem

An optical module according to the present disclosure includes: a base part provided on a top surface side of the stem, and having a bottom surface portion opposed to the top surface of the stem, and a side surface portion along a direction perpendicular to the top surface of the stem; a sub mount provided on the side surface portion of the base part; a semiconductor integrated photonic device provided on the sub mount and composed of, from the bottom surface portion side of the base part, a semiconductor laser unit, an optical modulator unit, and an optical amplifier unit which are electrically independent of each other; a semiconductor-laser-unit capacitor connected to the semiconductor laser unit of the semiconductor integrated photonic device; an optical-modulator-unit capacitor connected to the optical modulator unit of the semiconductor integrated photonic device; and an optical-amplifier-unit capacitor connected to the optical amplifier unit of the semiconductor integrated photonic device.

### Effect of the Invention

In the optical module according to the present disclosure, currents flow independently via capacitors electrically connected respectively to the semiconductor laser unit, the optical modulator unit, and the optical amplifier unit of the mounted semiconductor integrated photonic device, thus providing an effect of obtaining an optical module that is high in current controllability and enables size reduction.

### BRIEF DESCRIPTION OF THE DRAWINGS

FIG. 1 is an overall view of an optical module according to Embodiment 1;

FIG. 2 is a side view of the optical module according to Embodiment 1;

FIG. 3 is a side view of the optical module according to Embodiment 1;

FIG. 4 is a sectional view of a semiconductor integrated photonic device which is a part of the optical module according to Embodiment 1;

FIG. 5 is an overall view of a CAN package which is a part of the optical module according to Embodiment 1;

FIG. 6 is an overall view of an optical module according to Embodiment 2;

FIG. 7 is a side view of the optical module according to Embodiment 2;

FIG. 8 is a side view of the optical module according to Embodiment 2;

FIG. 9 is an overall view of an optical module according to Embodiment 3;

FIG. 10 is a side view of the optical module according to Embodiment 3;

FIG. 11 is a side view of the optical module according to Embodiment 3;

FIG. 12 is an overall view of the optical module according to Embodiment 4;

FIG. 13 is a side view of the optical module according to Embodiment 4;

FIG. 14 is a side view of the optical module according to Embodiment 4;

FIG. 15 is an overall view of an optical module according to Embodiment 5;

FIG. 16 is a side view of the optical module according to Embodiment 5;

FIG. 17 is a side view of the optical module according to Embodiment 5.

### DESCRIPTION OF EMBODIMENTS

### Embodiment 1

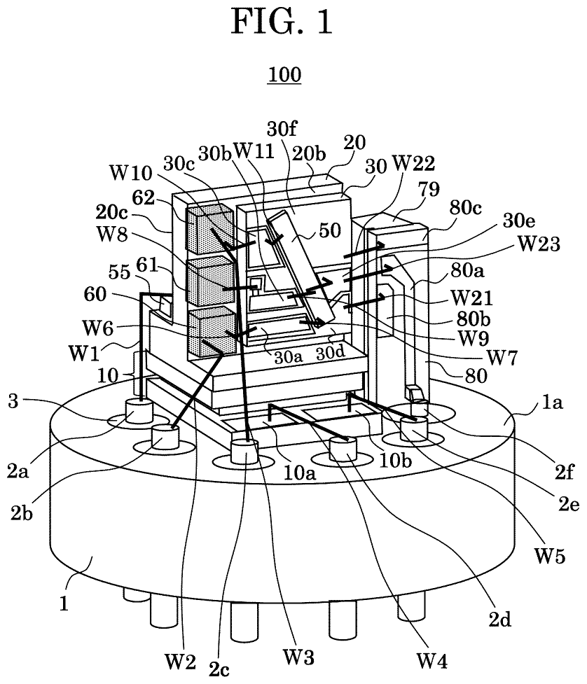

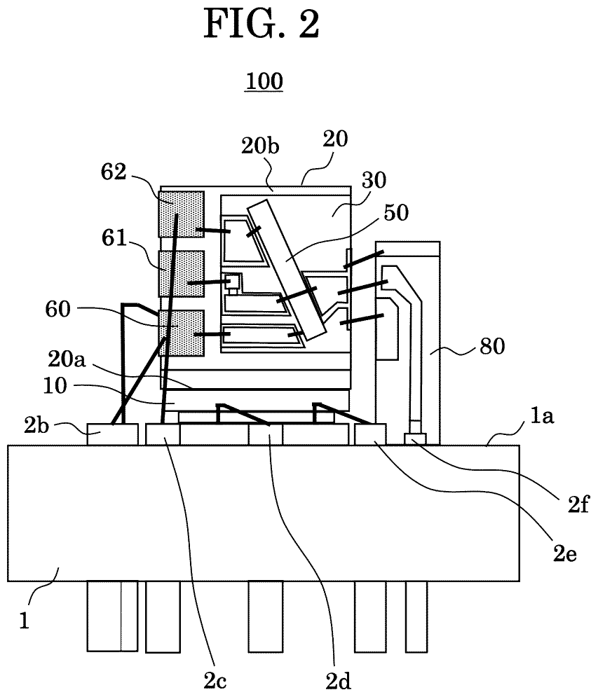

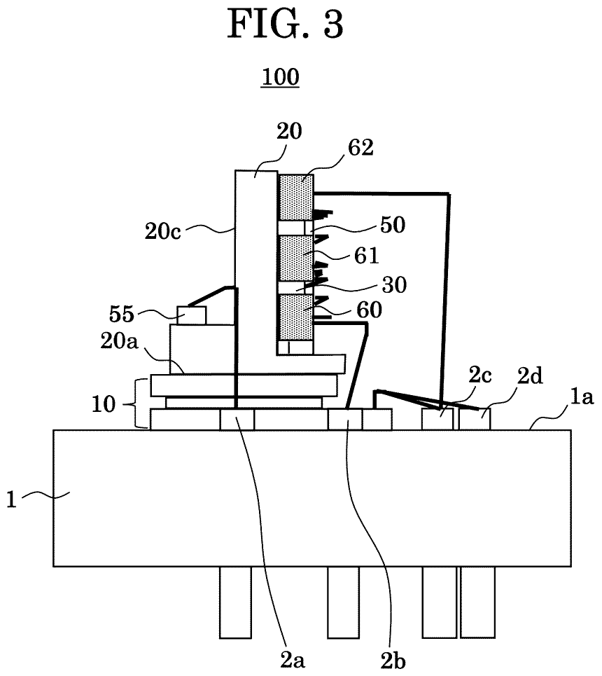

FIG. 1 is an overall view of an optical module 100 according to Embodiment 1. FIG. 2 and FIG. 3 are side views of the optical module 100 according to Embodiment 1.

A stem 1 has a substantially circular plate shape. The stem 1 is formed by performing Au plating or the like on a surface of a material having a high thermal conductivity such as copper (Cu), for example. The stem 1 is provided with a plurality of lead pins 2a to 2f penetrating the stem 1.

In order to fix the lead pins 2a to 2f to the stem 1, glass 3 is generally used. If impedance mismatch occurs, a signal undergoes multiplexed reflection, so that frequency response characteristics are deteriorated and it becomes difficult to perform high-speed modulation. Therefore, the glass 3 is made of a material having a low permittivity.

A temperature control module 10 is provided on a top surface la of the stem. The top surface 1a of the stem refers to a flat surface on a side where the lead pins 2a to 2f partially protrude, of the stem 1 having a circular plate shape. The temperature control module 10 is configured such that, for example, a plurality of thermoelectric elements made of a material such as bismuth telluride (BiTe) are interposed between a lower board and an upper board made of a material such as aluminum nitride (AlN). The lower board of the temperature control module 10 has a protruding part protruding, relative to the upper board, in a direction parallel to the top surface la of the stem. Electrode patterns 10a and 10b for supplying power to a thermoelectric element (not shown) are provided at the protruding part. The temperature control module 10 is provided for controlling the temperature of a semiconductor integrated photonic device 50 described later. In the optical module 100 according to Embodiment 1, the temperature control module 10 may be omitted.

A base part 20 is provided on the top surface of the temperature control module 10. A bottom surface portion 20a of the base part is opposed to the top surface la of the stem via the temperature control module 10. The bottom surface portion 20a of the base part and the top surface of the temperature control module 10 are joined to each other by a joining material such as SnAgCu solder or AuSn solder, for example.

The base part 20 has side surface portions 20b and 20c of the base part. The base part 20 is formed from a block of a metal material obtained by performing Au plating on a surface of a material having a high thermal conductivity such as Cu, for example. The base part 20 that is a separate component from the stem 1 may be mounted to the stem 1, or the stem 1 and the base part 20 may be formed integrally.

A sub mount 30 is mounted to the side surface portion 20b of the base part. The sub mount 30 is a rectangular parallelepiped plate-shaped member made of a dielectric material, for example. The sub mount 30 is made of a ceramic material such as AIN, for example, and has an electrical insulation function and a heat transfer function. The sub mount 30 has a main surface and a back surface opposite to each other, and four side surfaces. The back surface of the sub mount 30 is located on the side surface portion 20b of the base part. A metal pattern is formed on the main surface of the sub mount 30.

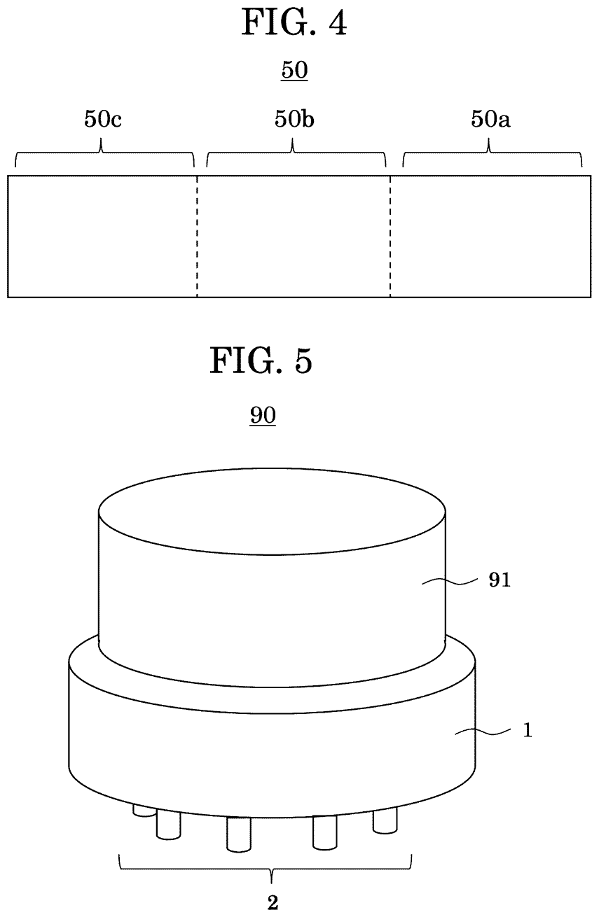

The semiconductor integrated photonic device 50 is provided on the main surface side of the sub mount 30. The semiconductor integrated photonic device 50 is composed of a semiconductor laser unit 50a, an optical modulator unit 50b, and an optical amplifier unit 50c as shown in a sectional view in FIG. 4. These units are arranged in an order of the semiconductor laser unit 50a, the optical modulator unit 50b, and then the optical amplifier unit 50c, from the bottom surface portion 20a side of the base part. The semiconductor laser unit 50a, the optical modulator unit 50b, and the optical amplifier unit 50c are electrically independent of each other. The semiconductor integrated photonic device 50 is mounted in an oblique direction relative to a direction perpendicular to the top surface la of the stem.

The semiconductor laser unit 50a of the semiconductor integrated photonic device 50 is composed of a distributed-feedback semiconductor laser (DFB laser), for example. The optical modulator unit 50b of the semiconductor integrated photonic device 50 is composed of an electro-absorption optical modulator using an InGaAsP-based quantum well absorption layer, for example. The optical amplifier unit 50c of the semiconductor integrated photonic device 50 is composed of an InGaAsP-based optical amplifier, for example.

An oscillation wavelength of the semiconductor integrated photonic device 50 varies depending on change in temperature. Therefore, the temperature of the semiconductor integrated photonic device 50 needs to be kept as constant as possible. If the temperature of the semiconductor integrated photonic device 50 increases, the temperature control module 10 performs cooling, and if the temperature of the semiconductor integrated photonic device 50 decreases, the temperature control module 10 generates heat, thereby keeping the temperature of the semiconductor integrated photonic device 50 constant.

Heat generated through driving of the semiconductor integrated photonic device 50 transfers to the upper board of the temperature control module 10 via the sub mount 30. The temperature control module 10 absorbs heat generated by the semiconductor integrated photonic device 50. Heat absorbed by the temperature control module 10 is dissipated from the lower board of the temperature control module 10 to a heat sink (not shown) on the back surface side of the stem 1 via the stem 1.

For the semiconductor integrated photonic device 50, on the side surface portion 20b of the base part, a semiconductor-laser-unit capacitor 60, an optical-modulator-unit capacitor 61, and an optical-amplifier-unit capacitor 62 are arranged in this order from the bottom surface portion 20a side of the base part, along a side surface in a direction perpendicular to the top surface la of the stem, of the sub mount 30 provided on the side surface portion 20b of the base part.

A thermistor 55 is provided at the side surface portion 20c of the base part on a side opposite to the side surface portion 20b of the base part on which the sub mount 30 is provided. The thermistor 55 is a kind of temperature sensor, and indirectly measures the temperature of the semiconductor integrated photonic device 50. The temperature measured by the thermistor 55 is fed back to the temperature control module 10. On the basis of the temperature measured by the thermistor 55, the temperature control module 10 performs temperature control for the semiconductor integrated photonic device 50, whereby the temperature of the semiconductor integrated photonic device 50 can be stabilized. As a result, a constant oscillation wavelength is stably obtained.

The lead pin 2a is electrically connected to the thermistor 55 via a conductive wire W1. The lead pin 2b is electrically connected to the semiconductor-laser-unit capacitor 60 via a conductive wire W2. The lead pin 2c is electrically connected to the optical-amplifier-unit capacitor 62 via a conductive wire W3. The lead pin 2d is electrically connected to the electrode pattern 10a of the temperature control module 10 via a conductive wire W4. The lead pin 2e is electrically connected to the electrode pattern 10b of the temperature control module 10 via a conductive wire W5. The lead pin 2f is electrically connected to an electrode pattern 80a of an auxiliary board 80 fixed to a side surface of an auxiliary block 79, and then is electrically connected to the optical modulator unit 50b of the semiconductor integrated photonic device 50 via an electrode pattern 30e on the sub mount 30. In FIG. 2 and FIG. 3, arrangement of the conductive wires and the electrode patterns is the same as in FIG. 1, and therefore reference characters of the conductive wires and the electrode patterns are not shown for the purpose of avoiding complication.

The semiconductor-laser-unit capacitor 60 is electrically connected to an electrode pattern 30a on the sub mount 30 via a conductive wire W6, and then is electrically connected to the semiconductor laser unit 50a of the semiconductor integrated photonic device 50 via a conductive wire W7.

The optical-modulator-unit capacitor 61 is electrically connected to an electrode pattern 30b on the sub mount 30 via a conductive wire W8, and then is electrically connected to the optical modulator unit 50b of the semiconductor integrated photonic device 50 via a conductive wire W9.

The optical-amplifier-unit capacitor 62 is electrically connected to an electrode pattern 30c on the sub mount 30 via a conductive wire W10, and then is electrically connected to the optical amplifier unit 50c of the semiconductor integrated photonic device 50 via a conductive wire W11.

The electrode pattern 80a of the auxiliary board 80 is electrically connected to the electrode pattern 30e on the sub mount 30 via a conductive wire W23. An electrode pattern 80b of the auxiliary board 80 is electrically connected to an electrode pattern 30d on the sub mount 30 via a conductive wire W21. An electrode pattern 80c of the auxiliary board 80 is electrically connected to an electrode pattern 30f on the sub mount 30 via a conductive wire W22.

As a package for the optical module 100 according to Embodiment 1, a CAN package 90 as shown in FIG. 5 is used. That is, the temperature control module 10, the base part 20, the sub mount 30, the auxiliary block 79, the auxiliary board 80, and the like provided on the top surface la side of the stem are stored inside a CAN case 91. Lead pins 2 protrude on the back surface side of the stem 1.

Since the above-described configuration is adopted in the optical module 100 according to Embodiment 1, current control can be individually performed for the semiconductor laser unit 50a, the optical modulator unit 50b, and the optical amplifier unit 50c via the semiconductor-laser-unit capacitor 60, the optical-modulator-unit capacitor 61, and the optical-amplifier-unit capacitor 62, respectively. Thus, controllability for driving current for the semiconductor integrated photonic device 50 is high. That is, an effect of improving current controllability of the optical module 100 according to Embodiment 1 is provided.

In addition, on the side surface portion 20b of the base part, the semiconductor-laser-unit capacitor 60, the optical-modulator-unit capacitor 61, and the optical-amplifier-unit capacitor 62 are arranged in this order from the bottom surface portion 20a side of the base part, along the side surface portion perpendicular to the top surface la of the stem, of the sub mount 30 provided on the side surface portion 20b of the base part. Thus, an effect of enabling size reduction of the optical module is provided.

### <Effect of Embodiment 1>

As described above, the optical module according to Embodiment 1 provides an effect of obtaining the following optical module: currents flow independently via capacitors electrically connected respectively to the semiconductor laser unit, the optical modulator unit, and the optical amplifier unit of the mounted semiconductor integrated photonic device, so that current controllability is high; and the capacitors are arranged in an order on the side surface portion of the base part, so that size reduction can be achieved.

### Embodiment 2

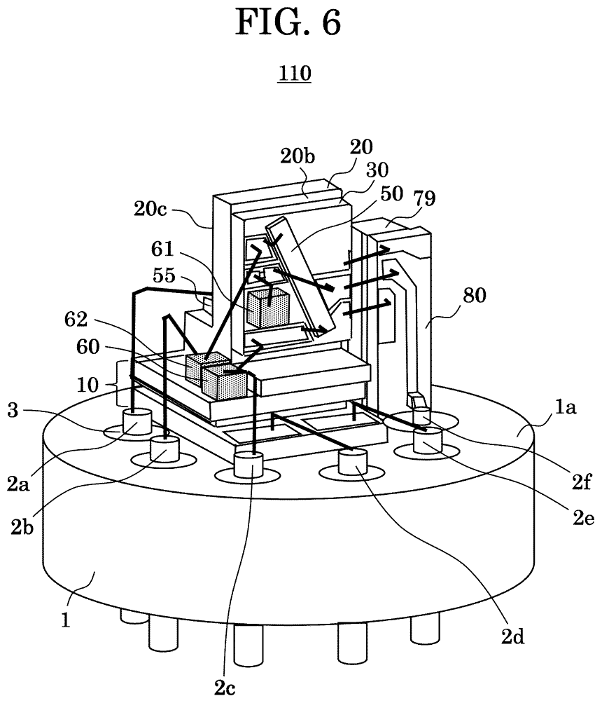

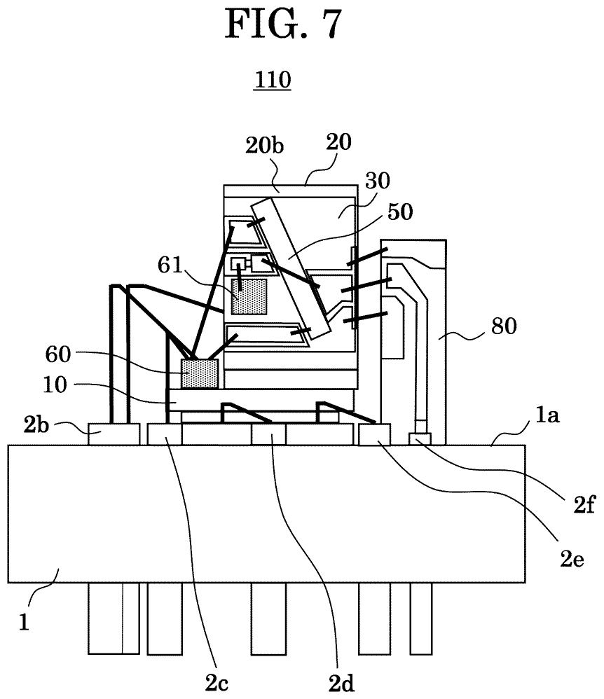

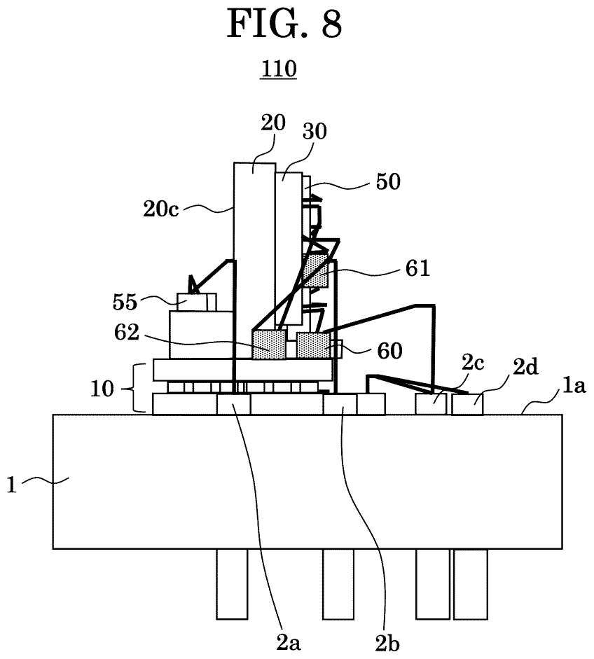

FIG. 6 is an overall view of an optical module 110 according to Embodiment 2. FIG. 7 and FIG. 8 are side views of the optical module 110 according to Embodiment 2.

Hereinafter, difference from the optical module 100 according to Embodiment 1 will be mainly described. In FIG. 6 to FIG. 8, arrangement of conductive wires and electrode patterns is the same as in Embodiment 1, and therefore reference characters thereof are not shown for the purpose of avoiding complication.

In the optical module 110 according to Embodiment 2, the optical-modulator-unit capacitor 61 is provided on the sub mount 30, as shown in FIG. 6 and FIG. 8. In addition, the semiconductor-laser-unit capacitor 60 and the optical-amplifier-unit capacitor 62 are provided on the top surface of the upper board of the temperature control module 10.

By arranging the capacitors as described above, the width along the side surface portion 20b of the base part can be reduced as compared to that in the structure of the optical module 100 according to Embodiment 1. That is, the CAN package 90 for storing the stem 1, the temperature control module 10, the base part 20, the sub mount 30, the auxiliary block 79, the auxiliary board 80, and the like of the optical module 110, can be downsized.

It is also possible to adopt a structure in which the area of the temperature control module 10 is the same as the area of the bottom surface portion 20a of the base part and the semiconductor-laser-unit capacitor 60 and the optical-amplifier-unit capacitor 62 are directly provided on the top surface la of the stem.

### <Effect of Embodiment 2>

As described above, the optical module according to Embodiment 2 provides an effect of obtaining the following optical module: currents flow independently via capacitors electrically connected respectively to the semiconductor laser unit, the optical modulator unit, and the optical amplifier unit of the mounted semiconductor integrated photonic device, so that current controllability is high; and the optical-modulator-unit capacitor is provided on the sub mount, and the semiconductor-laser-unit capacitor and the optical-amplifier-unit capacitor are provided on the temperature control module, so that size reduction can be achieved.

### Embodiment 3

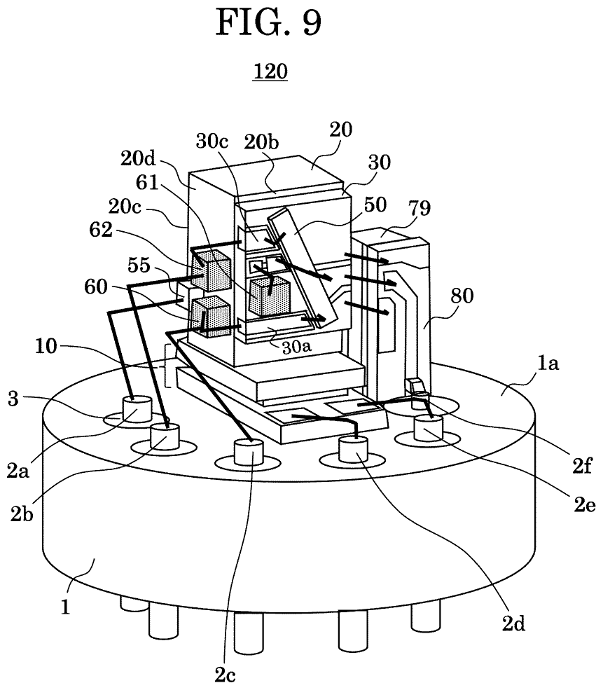

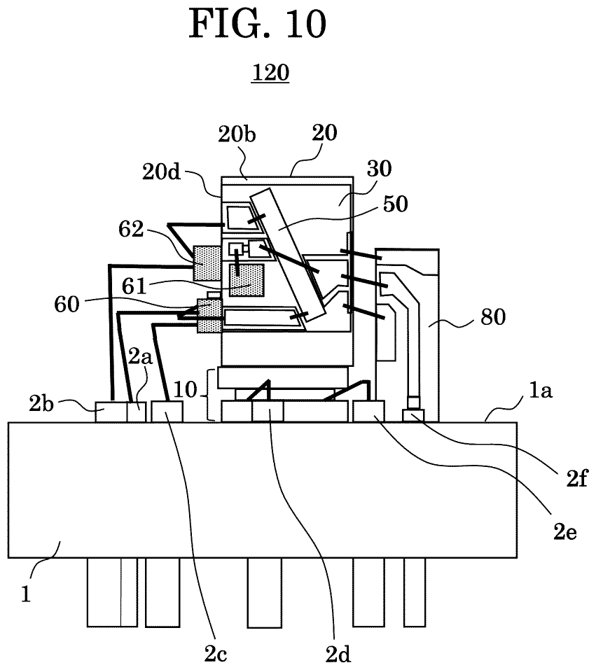

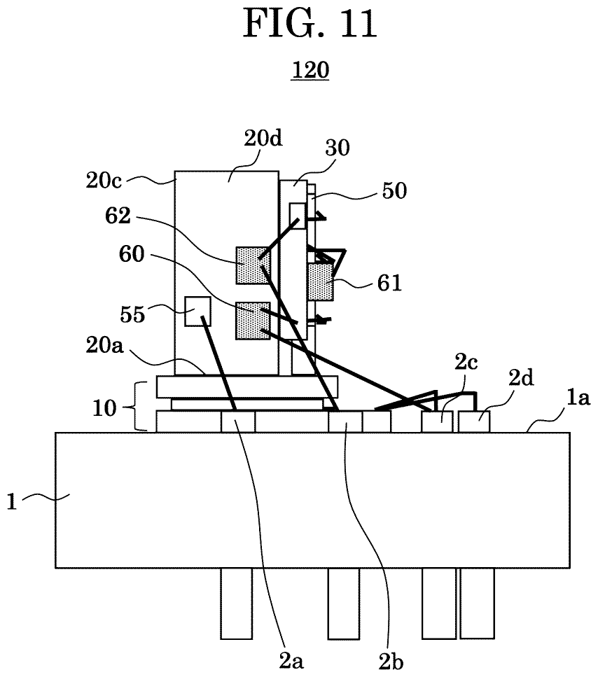

FIG. 9 is an overall view of an optical module 120 according to Embodiment 3. FIG. 10 and FIG. 11 are side views of the optical module 120 according to Embodiment 3. Hereinafter, difference from the optical module 100 according to Embodiment 1 will be mainly described. In FIG. 9 to FIG. 11, arrangement of conductive wires and electrode patterns is the same as in Embodiment 1, and therefore reference characters thereof are not shown for the purpose of avoiding complication.

In the optical module 120 according to Embodiment 3, as shown in FIG. 9 to FIG. 11, the base part 20 has a rectangular parallelepiped shape. In addition, the electrode pattern 30a and the electrode pattern 30c on the sub mount 30 are partially provided also on the side surface portion of the sub mount 30.

In the optical module 120 according to Embodiment 3, the optical-modulator-unit capacitor 61 is provided on the sub mount 30, as shown in FIG. 9 to FIG. 11. In addition, the semiconductor-laser-unit capacitor 60 and the optical-amplifier-unit capacitor 62 are provided on a side surface portion 20d of the base part. The side surface portion 20d of the base part refers to a side surface portion closer to the optical-modulator-unit capacitor 61, of two side surface portions in a direction perpendicular to the side surface portion 20b of the base part and the side surface portion 20c of the base part opposite to each other.

That is, the optical-modulator-unit capacitor 61 is provided on the sub mount 30, and the semiconductor-laser-unit capacitor 60 and the optical-amplifier-unit capacitor 62 are provided on another side surface portion 20d of the base part along the side surface portion 20b of the base part on which the sub mount 30 is provided.

The reason why the electrode pattern 30a and the electrode pattern 30c are partially provided also on the side surface portion of the sub mount 30 is that such arrangement is needed for connecting the electrode pattern 30a and the semiconductor-laser-unit capacitor 60 provided on the side surface portion 20d of the base part and connecting the electrode pattern 30c and the optical-amplifier-unit capacitor 62 provided on the side surface portion 20d of the base part, by conductive wires. That is, it is technically difficult to directly connect each capacitor provided on the side surface portion 20d of the base part and the semiconductor integrated photonic device 50 provided on the side surface portion 20b of the base part, by conductive wires.

By arranging the capacitors as described above, the width along the side surface portion 20b of the base part can be reduced as compared to that in the structure of the optical module 100 according to Embodiment 1. That is, the CAN package 90 for storing the stem 1, the temperature control module 10, the base part 20, the sub mount 30, the auxiliary block 79, the auxiliary board 80, and the like of the optical module 120 can be downsized.

Instead of the configuration in which the electrode pattern 30a and the electrode pattern 30c on the sub mount 30 are partially provided on the side surface portion of the sub mount 30, small-sized conductive blocks may be respectively joined onto the electrode pattern 30a and the electrode pattern 30c of the sub mount 30, and the conductive blocks may be connected to the semiconductor-laser-unit capacitor 60 and the optical-amplifier-unit capacitor 62 by conductive wires.

### <Effect of Embodiment 3>

As described above, the optical module according to Embodiment 3 provides an effect of obtaining the following optical module: currents flow independently via capacitors electrically connected respectively to the semiconductor laser unit, the optical modulator unit, and the optical amplifier unit of the mounted semiconductor integrated photonic device, so that current controllability is high; and the optical-modulator-unit capacitor is provided on the sub mount, and the semiconductor-laser-unit capacitor and the optical-amplifier-unit capacitor are provided on another side surface portion of the base part, so that further size reduction can be achieved.

### Embodiment 4

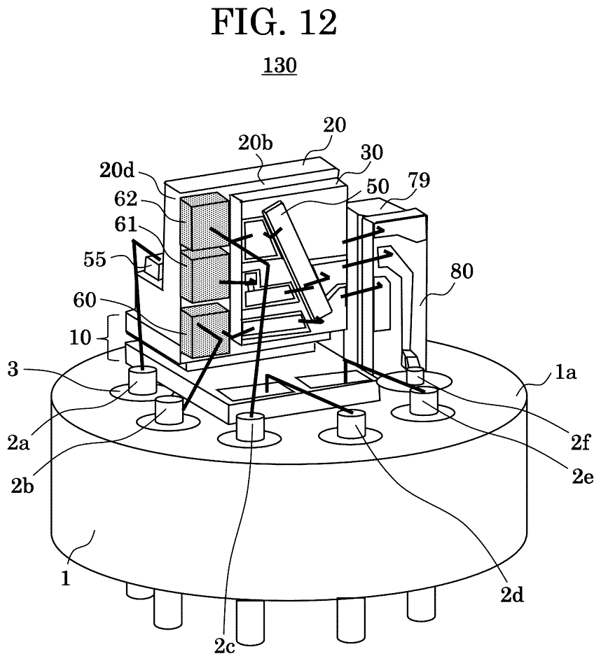

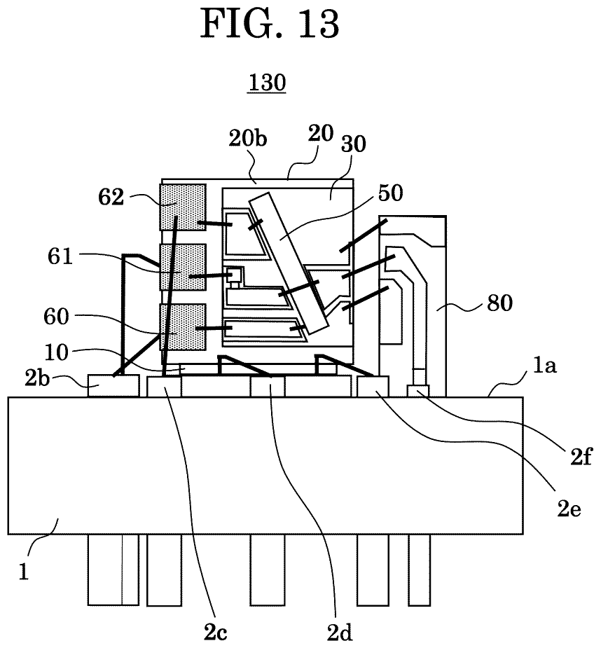

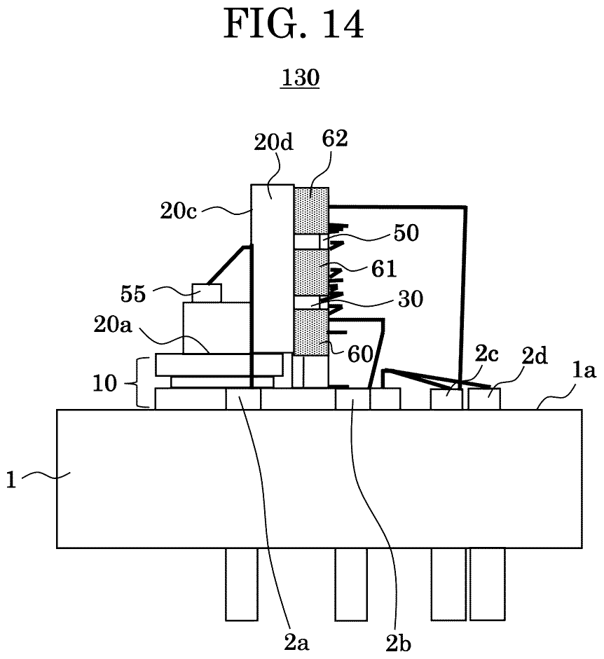

FIG. 12 is an overall view of an optical module 130 according to Embodiment 4. FIG. 13 and FIG. 14 are side views of the optical module 130 according to Embodiment 4. Hereinafter, difference from the optical module 100 according to Embodiment 1 will be mainly described. In FIG. 12 to FIG. 14, arrangement of conductive wires and electrode patterns is the same as in Embodiment 1, and therefore reference characters thereof are not shown for the purpose of avoiding complication.

In the optical module 130 according to Embodiment 4, arrangement of capacitors is the same as in the optical module 100 according to Embodiment 1, as shown in FIG. 12 to FIG. 14. The optical module 130 according to Embodiment 4 has a feature that the sectional shape of another side surface portion 20d of the base part along the side surface portion 20b of the base part on which the sub mount 30 is provided is an L shape.

When the sectional shape of the side surface portion 20d of the base part is an L shape, the height of the base part 20 from the top surface la of the stem can be reduced as compared to the height of the base part of the optical module 100 according to Embodiment 1. As a result, the CAN package 90 for storing the stem 1, the temperature control module 10, the base part 20, the sub mount 30, the auxiliary block 79, the auxiliary board 80, and the like of the optical module 130 can be downsized.

### <Effect of Embodiment 4>

As described above, the optical module according to Embodiment 4 provides an effect of obtaining the following optical module: currents flow independently via capacitors electrically connected respectively to the semiconductor laser unit, the optical modulator unit, and the optical amplifier unit of the mounted semiconductor integrated photonic device, so that current controllability is high; and the sectional shape of the side surface portion of the base part is an L shape, so that further size reduction can be achieved.

### Embodiment 5

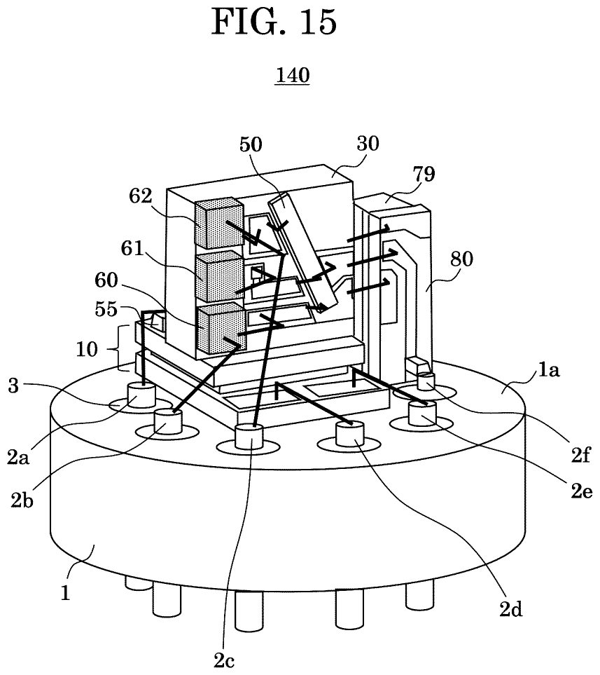

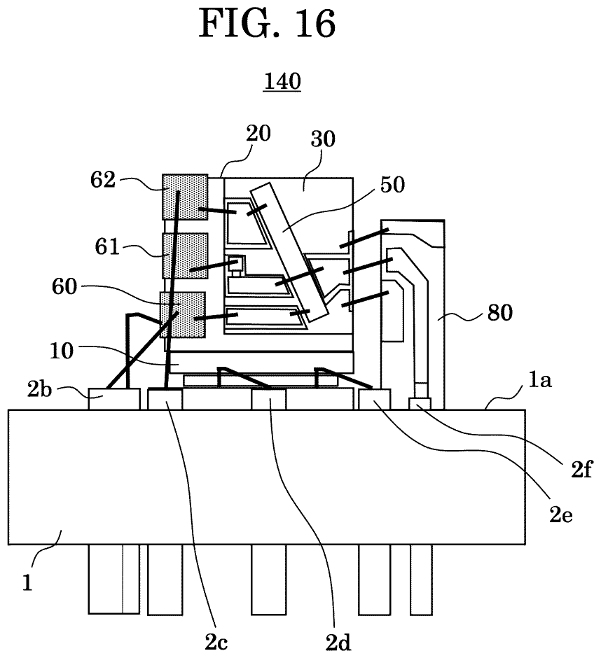

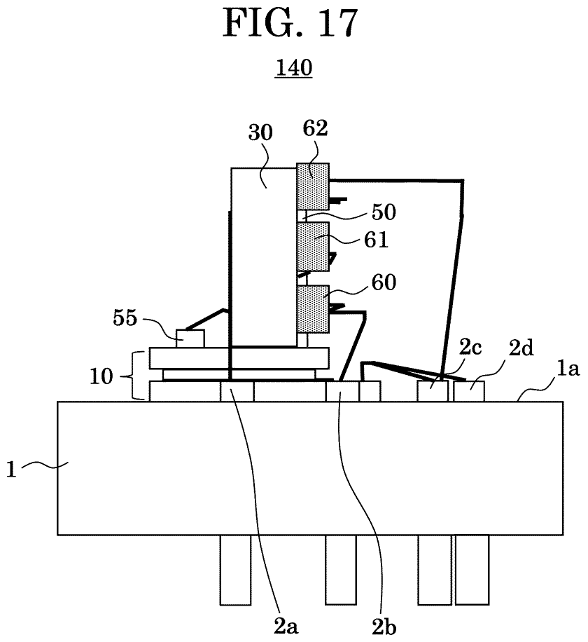

FIG. 15 is an overall view of an optical module 140 according to Embodiment 4. FIG. 16 and FIG. 17 are side views of the optical module 140 according to Embodiment 4. In FIG. 15 to FIG. 17, arrangement of conductive wires and electrode patterns is the same as in Embodiment 1, and therefore reference characters thereof are not shown for the purpose of avoiding complication.

The optical module 140 according to Embodiment 5 has a feature that the base part 20 is absent and instead the sub mount 30 serves also as the base part, as shown in FIG. 15 and FIG. 17. Arrangement of capacitors is the same as in the optical module 100 according to Embodiment 1.

In the optical module 140 according to Embodiment 5, since it is not necessary to provide the base part 20 as in Embodiments 1 to 4, the number of components can be decreased for the optical module. In addition, since the height of the sub mount 30 is smaller than the height of the base part 20 in Embodiments 1 to 4, the CAN package 90 for storing the stem 1, the temperature control module 10, the sub mount 30, the auxiliary block 79, the auxiliary board 80, and the like of the optical module 140 can be downsized.

### <Effect of Embodiment 5>

As described above, the optical module according to Embodiment 5 provides an effect of obtaining the following optical module: currents flow independently via capacitors electrically connected respectively to the semiconductor laser unit, the optical modulator unit, and the optical amplifier unit of the mounted semiconductor integrated photonic device, so that current controllability is high; and the base part can be omitted and thus the number of components of the optical module can be decreased, so that size reduction and cost reduction can be achieved.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 stem
1a top surface of stem
2, 2a, 2b, 2c, 2d, 2e, 2f lead pin
3 glass
10 temperature control module
10a, 10b, 30a, 30b, 30c, 30d, 30e, 30f, 80a, 80b, 80c electrode pattern
20 base part
20a bottom surface portion of base part
20b, 20c, 20d side surface portion of base part
30 sub mount
50 semiconductor integrated photonic device
50a semiconductor laser unit
50b optical modulator unit
50c optical amplifier unit
55 thermistor
60 semiconductor-laser-unit capacitor
61 optical-modulator-unit capacitor
62 optical-amplifier-unit capacitor
79 auxiliary block
80 auxiliary board
90 CAN package
91 CAN case
100, 110, 120, 130, 140 optical module
W1, W2, W3, W4, W5, W6, W7, W8, W9, W10, W11, W21, W22, W23 conductive wire

1. An optical module comprising:
a stem;
a base part provided on a top surface side of the stem, and having a bottom surface portion opposed to the top surface of the stem, and a side surface portion along a direction perpendicular to the top surface of the stem;
a sub mount provided on the side surface portion of the base part;
a semiconductor integrated photonic device provided on the sub mount and composed of, from the top surface side of the stem, a semiconductor laser unit, an optical modulator unit, and an optical amplifier unit which are electrically independent of each other;
a semiconductor-laser-unit capacitor connected to the semiconductor laser unit of the semiconductor integrated photonic device;
an optical-modulator-unit capacitor connected to the optical modulator unit of the semiconductor integrated photonic device; and
an optical-amplifier-unit capacitor connected to the optical amplifier unit of the semiconductor integrated photonic device.

2. An optical module comprising:
a stem;
a sub mount provided on a top surface side of the stem, and having a bottom surface portion opposed to the top surface of the stem, and a side surface portion along a direction perpendicular to the top surface of the stem;
a semiconductor integrated photonic device provided on the sub mount and composed of, from the top surface side of the stem, a semiconductor laser unit, an optical modulator unit, and an optical amplifier unit which are electrically independent of each other;
a semiconductor-laser-unit capacitor electrically connected to the semiconductor laser unit of the semiconductor integrated photonic device;
an optical-modulator-unit capacitor electrically connected to the optical modulator unit of the semiconductor integrated photonic device; and
an optical-amplifier-unit capacitor electrically connected to the optical amplifier unit of the semiconductor integrated photonic device.

3. The optical module according to claim 1, wherein
a temperature control module is provided between the stem and the base part.

4. The optical module according to claim 2, wherein
a temperature control module is provided between the stem and the sub mount.

5. The optical module according to claim 1, wherein
the sub mount is formed by a plate-shaped member, and
on the side surface portion of the base part, the semiconductor-laser-unit capacitor, the optical-modulator-unit capacitor, and the optical-amplifier-unit capacitor are arranged in this order from the bottom surface portion side of the base part, along a side surface portion in the direction perpendicular to the top surface of the stem, of the sub mount provided on the side surface portion of the base part.

6. The optical module according to claim 1, wherein
the sub mount has a rectangular parallelepiped shape, the optical-modulator-unit capacitor is provided on the sub mount, and the semiconductor-laser-unit capacitor and the optical-amplifier-unit capacitor are provided on the temperature control module.

7. The optical module according to claim 1, wherein
the sub mount has a rectangular parallelepiped shape, the optical-modulator-unit capacitor is provided on the sub mount, and the semiconductor-laser-unit capacitor and the optical-amplifier-unit capacitor are provided on another side surface portion along the side surface portion on which the sub mount is provided, of the base part.

8. The optical module according to claim 1, wherein
a sectional shape of another side surface portion along the side surface portion on which the sub mount is provided, of the base part, is an L shape.

9. The optical module according to claim 1, wherein
the semiconductor integrated photonic device is provided obliquely relative to the direction perpendicular to the top surface of the stem.

10. The optical module according to claim 1, wherein
the semiconductor integrated photonic device is stored in a CAN package.

11. The optical module according to claim 3, wherein
the sub mount is formed by a plate-shaped member, and
on the side surface portion of the base part, the semiconductor-laser-unit capacitor, the optical-modulator-unit capacitor, and the optical-amplifier-unit capacitor are arranged in this order from the bottom surface portion side of the base part, along a side surface portion in the direction perpendicular to the top surface of the stem, of the sub mount provided on the side surface portion of the base part.

12. The optical module according to claim 3, wherein
the sub mount has a rectangular parallelepiped shape, the optical-modulator-unit capacitor is provided on the sub mount, and the semiconductor-laser-unit capacitor and the optical-amplifier-unit capacitor are provided on the temperature control module.

13. The optical module according to claim 3, wherein
the sub mount has a rectangular parallelepiped shape, the optical-modulator-unit capacitor is provided on the sub mount, and the semiconductor-laser-unit capacitor and the optical-amplifier-unit capacitor are provided on another side surface portion along the side surface portion on which the sub mount is provided, of the base part.

14. The optical module according to claim 3, wherein
a sectional shape of another side surface portion along the side surface portion on which the sub mount is provided, of the base part, is an L shape.

15. The optical module according to claim 2, wherein
the semiconductor integrated photonic device is provided obliquely relative to the direction perpendicular to the top surface of the stem.

16. The optical module according to claim 2, wherein
the semiconductor integrated photonic device is stored in a CAN package.
